(19) United States
(12) Patent Application Publication
(10) Pub. No.: US 2024/0276795 A1
(43) Pub. Date: Aug. 15, 2024

(54) DISPLAY DEVICE

(71) Applicant: Sharp Display Technology Corporation, Kameyama City, Mie (JP)

(72) Inventor: Tadayoshi MIYAMOTO, Kameyama City, Mie (JP)

(21) Appl. No.: 18/564,814

(22) PCT Filed: Jul. 13, 2021
(86) PCT No.: PCT/JP2021/026326

§ 371 Date: Nov. 28, 2023

(51) Int. Cl. H10K 59/124; G09G 3/3233

(52) U.S. Cl. CPC H10K 59/124; G09G 3/3233; G09G 2300/0819; G09G 2300/0842; G09G 2300/0861

(57) ABSTRACT

A first TFT includes: a first semiconductor layer formed of polysilicon; and a first gate electrode provided to the first semiconductor layer toward a resin substrate through a first gate insulating film. A second TFT includes: a second semiconductor layer formed of oxide semiconductor and positioned more distant from the resin substrate than the first semiconductor layer; and a second gate electrode provided to the second semiconductor layer across from the resin substrate through a second gate insulating film.

### TECHNICAL FIELD

The present invention relates to a display device.

### BACKGROUND ART

In recent years, light-emitting organic electroluminescence (EL) display devices using organic EL elements have attracted attention as a replacement for liquid crystal display devices. An organic EL display device is provided with a plurality of thin-film transistors (hereinafter also referred to as “TFTs”) for each of subpixels. A subpixel is a minimum unit of an image. Here, examples of a well-known semiconductor layer constituting a TFT include: a semiconductor layer made of polysilicon having high mobility, and a semiconductor layer made of oxide semiconductor such as In—Ga—Zn—O and generating a low leakage current.

For example, Patent Document 1 discloses a display device having a hybrid structure in which a first TFT made of polysilicon semiconductor and a second TFT made of oxide semiconductor are formed on a substrate.

### CITATION LIST

### Patent Literature

[Patent Document 1] Japanese Unexamined Patent Application Publication No. 2020-017558 (FIGS. 5 and 6)

### SUMMARY OF INVENTION

### Technical Problems

Proposed organic EL display devices use a flexible resin substrate instead of a conventional glass substrate. Here, the resin substrate contains a large amount of impurity ions.

Hence, for example, if the display device having the hybrid structure disclosed in Patent Document 1 uses a resin substrate as the TFT substrate, impurity ions in the resin substrate inevitably diffuse when the TFTs are operated. The diffusion of the impurity ions could cause an adverse effect on the first TFT formed of polysilicon semiconductor and provided close to the resin substrate. Accordingly, characteristics of the first TFT become unstable, and the display quality inevitably deteriorates.

The present invention is conceived in view of the above problems, and directed to a display device having a hybrid structure using a resin substrate. For the display device, an object of the present invention is to stabilize the characteristics of a TFT formed of polysilicon semiconductor.

### Solution to Problems

In order to achieve the above object, a display device according to the present invention includes: a resin substrate; and a thin-film transistor layer provided on the resin substrate. The thin-film transistor layer includes a first thin-film transistor and a second thin-film transistor layer both provided for each of subpixels. The first thin-film transistor layer has a first semiconductor layer formed of polysilicon, and a second thin-film transistor has a second semiconductor layer formed of oxide semiconductor. The first thin-film transistor includes: the first semiconductor layer including a first conductor region and a second conductor region defined to be spaced apart from each other; a first gate electrode provided to the first semiconductor layer toward the resin substrate through a first gate insulating film, and controlling conduction between the first conductor region and the second conductor region; and a first terminal electrode and a second terminal electrode provided to the first semiconductor layer across from the resin substrate, spaced apart from each other, and respectively and electrically connected to the first conductor region and the second conductor region. The second thin-film transistor includes: the second semiconductor layer including a third conductor region and a fourth conductor region positioned more distant from the resin substrate than the first semiconductor layer, and defined to be spaced apart from each other; a second gate electrode provided to the second semiconductor layer across from the resin substrate through a second gate insulating film, and controlling conduction between the third conductor region and the fourth conductor region; and a third terminal electrode and a fourth terminal electrode provided to the second gate electrode across from the resin substrate, spaced apart from each other, and respectively and electrically connected to the third conductor region and the fourth conductor region.

### Advantageous Effect of Invention

The present invention is directed to a display device having a hybrid structure using a resin substrate. For the display device, the present invention can stabilize the characteristics of a TFT formed of polysilicon semiconductor.

### BRIEF DESCRIPTION OF DRAWINGS

FIG. 1 is a plan view of a schematic configuration of an organic EL display device according to a first embodiment of the present invention.

FIG. 2 is a plan view of a display region of the organic EL display device according to the first embodiment of the present invention.

FIG. 3 is a cross-sectional view of the display region of the organic EL display device according to the first embodiment of the present invention.

FIG. 4 is an equivalent circuit diagram of the EL display device according to the first embodiment of the present invention.

FIG. 5 is a cross-sectional view of an organic EL layer included in the organic EL display device according to the first embodiment of the present invention.

FIG. 6 is a cross-sectional view of a display region of an organic EL display device according to a second embodiment of the present invention. FIG. 6 corresponds to FIG. 3.

### DESCRIPTION OF EMBODIMENTS

Embodiments of the present invention will be described in detail below with reference to the drawings. Note that the present invention shall not be limited to the embodiments below.

### First Embodiment

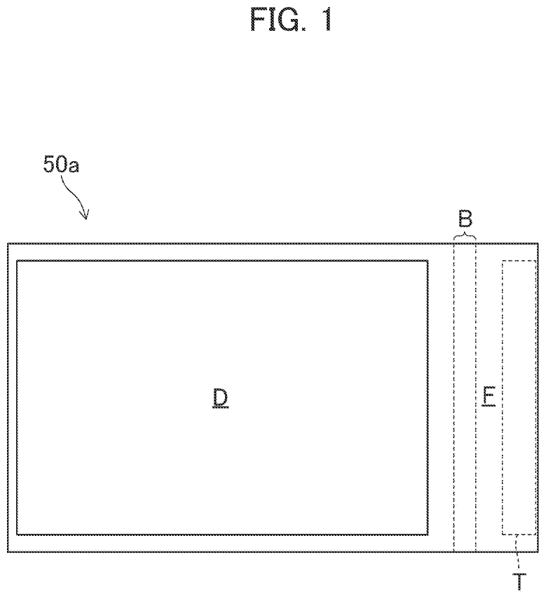

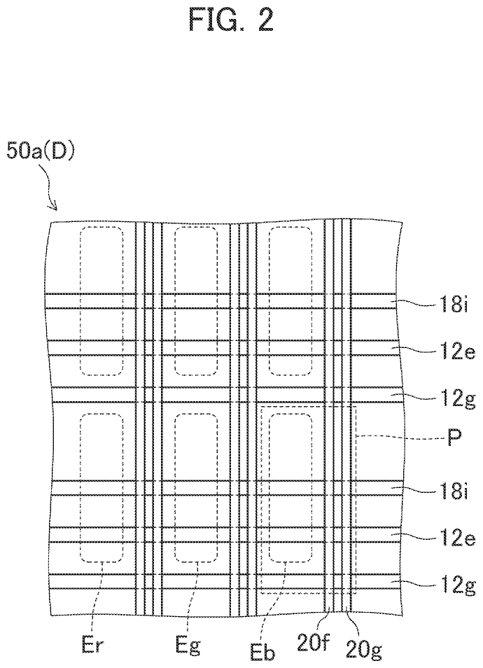

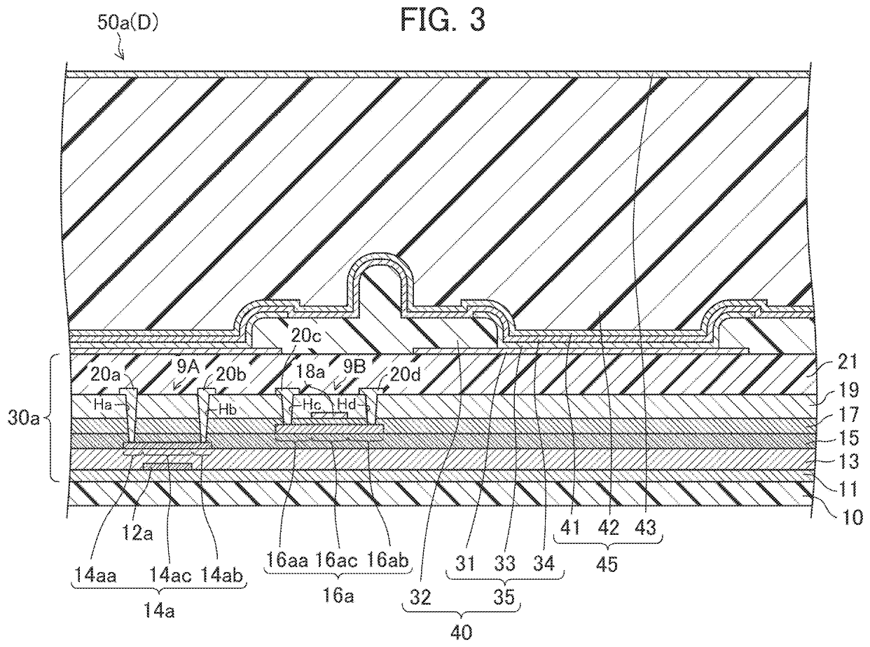

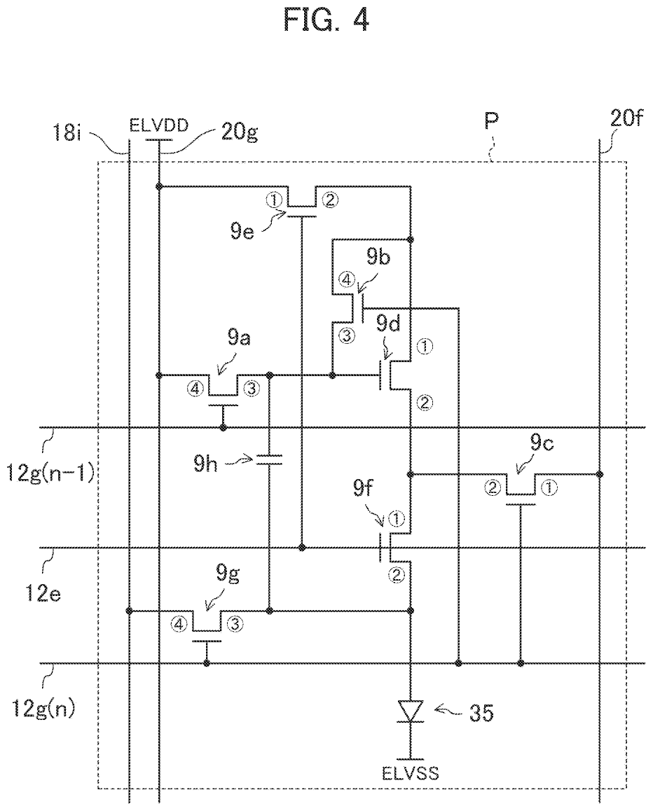

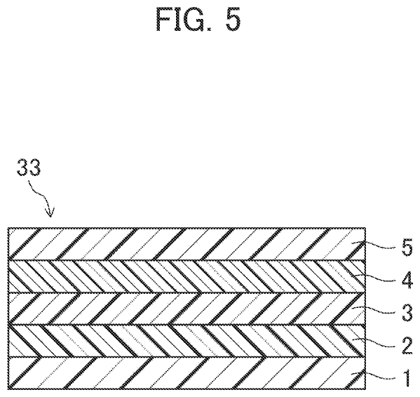

FIGS. 1 to 5 illustrate a first embodiment of a display device according to the present invention. Note that, in the embodiments below-, an organic EL display device including an organic EL element layer is exemplified as a display device including a light-emitting element layer. Here, FIG. 1 is a plan view of a schematic configuration of an organic EL display device 50a according to this embodiment. Furthermore, FIG. 2 and FIG. 3 are respectively a plan view and a cross-sectional view of a display region D of the organic EL display device 50a. Moreover, FIG. 4 is an equivalent circuit diagram of the organic EL display device 50a. In addition, FIG. 5 is a cross-sectional view of an organic EL layer 33 included in the organic EL display device 50a.

As illustrated in FIG. 1, the organic EL display device 50a includes, for example: the display region D shaped into a rectangle and displaying an image; and a picture-frame region F provided around the display region D. Note that this embodiment exemplifies the display region D shaped into a rectangle. Examples of die rectangle include such substantial rectangles as a rectangle having arc-like sides, a rectangle having rounded corners, and a rectangle having partially notched sides.

The display region D illustrated in FIG. 2 includes a plurality of subpixels P arranged in a matrix. Moreover, in the display region D, as illustrated in FIG. 2, for example, subpixels P having red light-emitting regions Er for presenting red, subpixels P having green light-emitting regions Eg for presenting green, and subpixels P having blue light-emitting regions Eb for presenting blue are provided side by side. Note that, in the display region D, for example, neighboring three subpixels P each having one of a red light-emitting region Er, a green light-emitting region Eg, and a blue light-emitting region Eb constitute one pixel.

The picture-frame region F in FIG. 1 has a right end portion provided with a terminal unit T. Moreover, as illustrated in FIG. 1, the picture-frame region F includes a folding portion B between the display region D and the terminal unit T. The folding portion B, extending in one direction (in the vertical direction in the drawing), is foldable around a folding axis in the vertical direction in the drawing at an angle of 180° (foldable in a U-shape).

As illustrated in FIG. 3, the organic EL display device 50a includes: a resin substrate layer 10, a TFT layer 30a provided on the resin substrate layer 10; an organic EL element layer 40 provided on the TFT layer 30a and serving as a light-emitting element layer; and a sealing film 45 provided to cover the organic EL element layer 40.

The resin substrate 10 is made of, for example, such a material as polyimide resin.

The TFT layer 30a illustrated in FIG. 3 includes: a base coat film 11 provided on the resin substrate 10; four first TFTs 9A, three second TFTs 9B, and one capacitor 9h all of which are provided on the base coat film 11 for each of the subpixels P (see FIG. 4); and a planarization film 21 provided on each of the first TFTs 9A, the second TFTs 9B, and the capacitor 9hl. Here, the TFT layer 30a includes, as illustrated in FIG. 2, a plurality of gate lines 12g extending in parallel with one another in the horizontal direction in the drawing. Furthermore, the TFT layer 30a includes, as illustrated in FIG. 2, a plurality of light-emission control lines 12e extending in parallel with one another in the horizontal direction in the drawing. Moreover, the TFT layer 30a includes, as illustrated in FIG. 2, a plurality of second initialization power supply lines 18i extending in parallel with one another in the horizontal direction in the drawing. Note that, as illustrated in FIG. 2, the light-emission control lines 12e are provided side-by-side with the gate lines 12g and the second initialization power supply lines 18i. In addition, the TFT layer 30a includes, as illustrated in FIG. 2, a plurality of source lines 20f extending in parallel with one another in the vertical direction in the drawing. Furthermore, the TFT layer 30a includes, as illustrated in FIG. 2, a plurality of power supply lines 20g extending in parallel with one another in the vertical direction in the drawing. Note that, as illustrated in FIG. 2, the power supply lines 20g and the source lines 20f are provided side by side.

As illustrated in FIG. 3, each of the first TFTs 9A includes: a first gate electrode 12a provided on the base coat film 11; a first gate insulating film 13 provided to cover the first gate electrode 12a, a first semiconductor layer 14a provided on the first gate insulating film 13; a first interlayer insulating film 15, a second gate insulating film 17, and a second interlayer insulating film 19 sequentially provided above the first semiconductor layer 14a; and a first terminal electrode 20a and a second terminal electrode 20b provided on the second interlayer insulating film 19 and spaced apart from each other.

Each of the base coat film 11, the first gate insulating film 13, the first interlayer insulating film 15, the second gate insulating film 17, and the second interlayer insulating film 19 is a monolayer film made of such a substance as, for example, silicon nitride, silicon oxide, or silicon oxide nitride. Alternatively, each film is a multilayer film made of these substances. Here, at least the first interlayer insulating film 15 and the second gate insulating film 17 have portions formed of silicon oxide films. These portions are provided close to second semiconductor layer 16a to be described later. Note that the first gate insulating film 13 (e.g., a multilayer film including a silicon oxide film (an upper layer) having a thickness of approximately 350 nm, a silicon nitride film (a middle layer) having a thickness of approximately 30 nm, and a silicon oxide film (a lower layer) having a thickness of approximately 200 nm) is thicker than the second gate insulating film 17 (e g., a monolayer film including a silicon oxide film having a thickness of approximately 150 nm).

As illustrated in FIG. 3, the first gate electrode 12a is provided to overlap with a first channel region 14ac of the first semiconductor layer 14a. The first gate electrode 12a controls conduction between a first conductor region 14aa and a second conductor region 14ab of the first semiconductor layer 14a. The first channel region 14ac, the first conductor region 14aa, and the second conductor region 14ab will be described later.

The first semiconductor layer 14a is formed of, for example, polysilicon such as low temperature polysilicon (LTPS). As illustrated in FIG. 3, the first semiconductor layer 14a includes the first conductor region 14aa and the second conductor region 14ab defined to be spaced apart from each other; and the first channel region 14ac defined between the first conductor region 14aa and the second conductor region 14ab.

The first terminal electrode 20a and the second terminal electrode 20b illustrated in FIG. 3 are respectively and electrically connected to the first conductor region 14aa and the second conductor region 14ab of the first semiconductor layer 14a through a first contact hole Ha and a second contact hole Hb formed in a multilayer film including the first interlayer insulating film 15, the second gate insulating film 17, and the second interlayer insulating film 19.

As illustrated in FIG. 3, each of the second TFTs 9B includes: the second semiconductor layer 16a provided on the first interlayer insulating film 15; the second gate insulating film 17 provided on the second semiconductor layer 16a; a second gate electrode 18a provided to the second gate insulating film 17; the second interlayer insulating film 19 provided to cover the second gate electrode 18a; and a third terminal electrode 20c and a fourth terminal electrode 20d provided on the second interlayer insulating film 19 and spaced apart from each other.

The second semiconductor layer 16a is formed of, for example, an In—Ga—Zn—O-based oxide semiconductor. As illustrated in FIG. 3, the second semiconductor layer 16a includes: a third conductor region 16aa and a fourth conductor region 16ab defined to be spaced apart from each other, and a second channel region 16ac defined between the third conductor region 16aa and the fourth conductor region 16ab. Furthermore, the second semiconductor layer 16a illustrated in FIG. 3 is positioned more distant from the resin substrate 10 than the first semiconductor layer 14a. Here, the In—Ga—Zn—O-based semiconductor is a ternary oxide of indium (In), gallium (Ga), and zinc (Zn), and a ratio (a composition ratio) of In to Ga to Zn shall not be limited to a particular ratio. Furthermore, the In—Ga—Zn—O-based semiconductor may be amorphous or crystalline. Note that the crystalline In—Ga—Zn—O-based semiconductor is preferably a crystalline In—Ga—Zn—O-based semiconductor in which the c-axis is oriented substantially perpendicular to the layer plane. Moreover, instead of the In—Ga—Zn—O-based semiconductor, the second semiconductor layer 16a may contain another oxide semiconductor Examples of the other oxide semiconductor may include an In—Sn—Zn—O-based semiconductor (e.g., In₂O₃—SnO₂—ZnO; InSnZnO). Here, the In—Sn—Zn—O-based semiconductor is a ternary oxide of indium (In), tin (Sn), and zinc (Zn). In addition, other oxide semiconductors may include: an In—Al—Zn—O-based semiconductor; an In—Al—Sn—Zn—O-based semiconductor; a Zn—O-based semiconductor; an In—Zn—O-based semiconductor, a Zn—Ti—O-based semiconductor, a Cd—Ge—O-based semiconductor; a Cd—Pb—O-based semiconductor; cadmium oxide (CdO); a Mg—Zn—O-based semiconductor; an In—Ga—Sn—O-based semiconductor; an In—Ga—O-based semiconductor; a Zr—In—Zn—O-based semiconductor, a Hf—In—Zn—O-based semiconductor; an Al—Ga—Zn—O-based semiconductor; a Ga—Zn—O-based semiconductor; an In—Ga—Zn—Sn—O-based semiconductor; InGaO₃ (ZnO)₅; zinc magnesium oxide (MgₓZn₁₋ₓO), and zinc cadmium oxide (CdₓZn₁₋ₓO). Note that the Zn—O-based semiconductor may be ZnO doped with one or more kinds of impurity elements among a group 1 element, a group 13 element, a group 14 element, a group 15 element, and a group 17 element. The Zn—O-based semiconductor may be in an amorphous state, in a polycrystalline state, or in a microcrystalline state in which an amorphous state and a polycrystalline state are mixed together. Alternatively, the Zn—O-based semiconductor does not have to be doped with any impurity element.

As illustrated in FIG. 3, the second gate electrode 18a is provided to overlap with the second channel region 16ac of the second semiconductor layer 16a. The second gate electrode 18a controls conduction between the third conductor region 16aa and the fourth conductor region 16ab of the second semiconductor layer 16a.

The third terminal electrode 20c and the fourth terminal electrode 20d illustrated in FIG. 3 are respectively and electrically connected to the third conductor region 16aa and the fourth conductor region 16ab of the second semiconductor layer 16a through a third contact hole Hc and a fourth contact hole Hd formed in a multilayer film including the second gate insulating film 17 and the second interlayer insulating film 19.

In this embodiment, p-channel TFTs such as a write TFT 9c, a drive TFT 9d, a power supply TFT 9e, and a light-emission control TFT 9f to be described later are exemplified as the four first TFTs 9A having the first semiconductor layer 14a formed of polysilicon, and n-channel TFTs such as an initialization TFT 9a, a compensation TFT 9b, and an anode discharge TFT 9g to be described later are exemplified as the three second TFTs 9B having the second semiconductor layer 16a formed of oxide semiconductor (see FIG. 4). Note that the four first TFTs 9A having the first semiconductor layer 14a formed of polysilicon may be n-channel TFTs. Moreover, in the equivalent circuit diagram in FIG. 4, the first terminal electrode 20a and the second terminal electrode 20b of each of the TFTs 9c, 9d, 9e, and 9f are denoted by circled numerals 1 and 2, and the third terminal electrode 20c and the fourth terminal electrode 20d of each of the TFTs 9a, 9b, and 9g are denoted by circled numerals 3 and 4. Furthermore, the equivalent circuit diagram of FIG. 4 illustrates a pixel circuit of a subpixel P at the n-th row and the m-th column. The equivalent circuit diagram also partially includes a pixel circuit of a subpixel P at the (n-1)-th row and the m-th column. In addition, in the equivalent circuit diagram in FIG. 4, the power supply line 20g to supply a high power-supply voltage ELVDD also serves as a first initialization power supply line; however, the power supply line 20g and the first initialization power supply line may be provided separately. Moreover, the second initialization power supply line 18i receives, but not limited to, the same voltage as a low power-supply voltage ELVSS. The second initialization power supply line 18i may receive a voltage that differs from the low power-supply voltage ELVSS, and that turns OFF an organic EL element 35 to be described later.

As illustrated in FIG. 4, in each subpixel P, the initialization TFT 9a has: a gate electrode electrically connected to a gate line 12g (n-1) in a preceding stage (n-1 stage); the third terminal electrode electrically connected to a lower conductive layer of the capacitor 9h and to a gate electrode of the drive TFT 9d; and the fourth terminal electrode electrically connected to a power supply line 20g.

As illustrated in FIG. 4, in each subpixel P, the compensation TFT 9b has: a gate electrode electrically connected to a gate line 12g (n) in a corresponding stage (n-th stage), the third terminal electrode electrically connected to the gate electrode of the drive TFT 9d, and the fourth terminal electrode electrically connected to the first terminal electrode of the drive TFT 9d.

As illustrated in FIG. 4, in each subpixel P, the write TFT 9c has: a gate electrode electrically connected to the gate line 12g (n) in the corresponding stage (n-th stage); the first terminal electrode electrically connected to a corresponding source line 20f; and the second terminal electrode electrically connected to the second terminal electrode of the drive TFT 9d.

As illustrated in FIG. 4, in each subpixel P, the drive TFT 9d has: the gate electrode electrically connected to the third terminal electrode of each of the initialization TFT 9a and the compensation TFT 9b; the first terminal electrode electrically connected to the fourth terminal electrode of the compensation TFT 9b and to the second terminal electrode of the power supply TFT 9e; and the second terminal electrode electrically connected to the second terminal electrode of the write TFT 9c and to the first terminal electrode of the light-emission control TFT 9f. Here, the drive TFT 9d controls a current of the organic EL element 35. Furthermore, in a first TFT 9A acting as the drive TFT 9d, the first gate insulating film 13 is thicker than the second gate insulating film 17. Such a feature can increase an S value of a subthreshold region in an Id-Vg characteristic, and the rise curve can be laid flat. Thus, the first TFT 9A can reduce a variation of a current with respect to a variation of a voltage. Such a feature can reduce luminance variation of the organic EL element 35, thereby successfully obtaining TFT characteristics suitable for the drive TFT 9d.

As illustrated in FIG. 4, in each subpixel P, the power supply TFT 9e has: a gate electrode electrically connected to a light-emission control line 12e in the corresponding stage (n-th stage); the first terminal electrode electrically connected to the power supply line 20g, and the second terminal electrode electrically connected to the first terminal electrode of die drive TFT 9d.

As illustrated in FIG. 4, in each subpixel P, the light-emission control TFT 9f has: a gate electrode electrically connected to the light-emission control line 12e in the corresponding stage (n-th stage); the first terminal electrode electrically connected to the second terminal electrode of the drive TFT 9d; and the second terminal electrode electrically connected to a first electrode 31 of the organic EL element 35. The first electrode 31 and the organic EL element 35 will be described later.

As illustrated in FIG. 4, in each subpixel P, the anode discharge TFT 9g has: a gate electrode electrically connected to the gate line 12g (n) in the corresponding stage (n-th stage); the third terminal electrode electrically connected to the first electrode 31 of the organic EL element 35; and the fourth terminal electrode electrically connected to a second initialization power supply line 18i.

The capacitor 9h includes, for example; a lower conductive layer (not shown) formed of the same material as, and in the same layer as, the second gate electrode 18a, the second interlayer insulating film 19 provided to cover the lower conductive layer; and an upper conductive layer (not shown) provided on the second interlayer insulating film 19 to overlap with the lower conductive layer, and formed of the same material as, and in the same layer as, the first terminal electrode 20a. Moreover, as illustrated in FIG. 4, in each subpixel P, the capacitor 9h has: the lower conductive layer electrically connected to the gate electrode of the drive TFT 9d and to the third terminal electrode of each of the initialization TFT 9a and the compensation TFT 9b, and the upper conductive layer electrically connected to the third terminal electrode of the anode discharge TFT 9g, to the second terminal electrode of the light-emission control TFT 9f, and to the first electrode 31 of the organic EL element 35.

The planarization film 21 has a flat surface in the display region D. The planarization film 21 is made of such a material as, for example, an organic resin material such as polyimide resin or acrylic resin, or a polysiloxane-based spin-on-glass (SOG) material.

As illustrated in FIG. 3, the organic EL element layer 40 includes: a plurality of the organic EL elements 35 provided to serve as a plurality of light-emitting elements corresponding to the plurality of respective subpixels P and arranged in a matrix; and an edge cover 32 provided in a lattice form common to all the subpixels P to cover a peripheral end portion of the first electrode 31 of each organic EL element 35.

As illustrated in FIG. 3, in each subpixel P, the organic EL element 35 includes: the first electrode 31 provided on the planarization film 21 of the TFT layer 30a; an organic EL layer 33 provided on the first electrode 31; and a second electrode 34 provided on the organic EL layer 33.

The first electrode 31 is electrically connected through a contact hole formed in the planarization film 21 to the second terminal electrode of the light-emission control TFT 9f for each subpixel P. Furthermore, the first electrode 31 has a function of injecting holes into the organic EL layer 33. Moreover, the first electrode 31 is preferably formed of a material having a large work function to improve efficiency in injecting the holes into the organic EL layer 33. Here, examples of the material forming the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Furthermore, the first electrode 31 may be made of for example, an alloy of astatine (At)/astatine oxide (AtO₂). Moreover, the first electrode 31 may be made of a conductive oxide such as, for example, tin oxide (SnO), zinc oxide (ZnO), indium tin oxide (ITO), or indium zinc oxide (IZO). In addition, the first electrode 31 may be formed of a plurality of layers made of the above materials and stacked on top of another. Note that examples of compound materials having a large work function include indium tin oxide (ITO) and indium zinc oxide (IZO).

As illustrated in FIG. 5, the organic EL layer 33 includes: a hole injection layer 1; a hole transport layer 2; a light-emitting layer 3, an electron transport layer 4, and an electron injection layer 5, all of which are provided in the stated order above the first electrode 31.

The hole injection layer 1 is also referred to as an anode buffer layer. The hole injection layer 1 has a function of approximating energy levels between the first electrode 31 and the organic EL layer 33 to improve efficiency in injecting the holes from the first electrode 31 into the organic EL layer 33. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the first electrode 31 to the organic EL layer 33. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are respectively injected from the first electrode 31 and the second electrode 34, and recombine together, when a voltage is applied with the first electrode 31 and the second electrode 34. Here, the light-emitting layer 3 is formed of a material having high light-emission efficiency. Examples of the material forming the light-emitting layer 3 include a metal oxinoid compound [8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to die light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 34 and the organic EL layer 33 to improve efficiency in injecting the electrons from the second electrode 34 into the organic EL layer 33. Such a function can decrease a drive voltage of the organic EL element 35. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃), and strontium oxide (SrO).

As illustrated in FIG. 3, the second electrode 34 is provided in common to all the subpixels P to cover each organic EL layer 33 and the edge cover 32. Moreover, the second electrode 34 has a function of injecting the electrons into the organic EL layer 33. Furthermore, the second electrode 34 is preferably formed of a material having a small work function to improve efficiency in injecting the electrons into the organic EL layer 33. Here, examples of the material forming the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the second electrode 34 may be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), or lithium fluoride (LiF)/calcium (Ca)/aluminum (Al). Furthermore, the second electrode 34 may be formed of a conductive oxide such as tin oxide (SnO), zinc oxide (ZnO), indium tin oxide (ITO), or indium zinc oxide (IZO). In addition, the second electrode 34 may be formed of a plurality of layers made of the above materials and stacked on top of another. Note that examples of the material having a small work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 32 is made of, for example, an organic resin material such as polyimide resin or acrylic resin, or a polysiloxane-based SOG material.

As illustrated in FIG. 3, the sealing film 45 is provided to cover the second electrode 34, and includes: a first inorganic sealing film 41; an organic sealing film 42; and a second inorganic sealing film 43, all of which are stacked on top of another in the stated order above the second electrode 34. The sealing film 45 has a function of protecting the organic EL layer 33 in the organic EL element layer 35 from moisture and oxygen.

Each of the first inorganic sealing film 41 and the second inorganic sealing film 43 is formed of such an inorganic insulating film as, for example, a silicon nitride film, a silicon oxide film, or a silicon oxynitride film.

The organic sealing film 42 is formed of such an organic resin material as, for example, acrylic resin, epoxy resin, silicone resin, polyurea resin, parylene resin, polyimide resin, or polyamide resin.

As to the organic EL display device 50a having the above configuration, in each subpixel P, when the light-emission control line 14e is first selected to be in an inactive state, the organic EL element 35 is in a non-light-emission state. In the non-light-emission state, the gate line 12g (n-1) in the preceding stage is selected. Through the gate line 12g (n-1), a gate signal is input into the initialization TFT 9a such that the initialization TFT 9a turns ON. Hence, the high power-supply voltage ELVDD of the power supply line 20g is applied to the capacitor 9h, and the drive TFT 9d turns ON. Thus, charges of the capacitor 9h are discharged, and a voltage to be applied to the gate electrode of the drive TFT 9d is initialized. Next, when the gate line 12g (n) of the corresponding stage is selected to be in the active state, the compensation TFT 9b and the write TFT 9c turn ON, and a predetermined voltage corresponding to a source signal to be transmitted through the corresponding source line 20f is written into the capacitor 9h through the drive TFT 9d connected to a diode. Simultaneously, the anode discharge TFT 9g turns ON, and an initialization signal is applied through the second initialization power supply line 18i to the first electrode 31 of the organic EL element 35. Hence, the charges stored in the first electrode 31 are reset. After that, the light-emission control line 12e is selected, and the power supply TFT 9e and the light-emission control TFT 9f turn ON. Hence, a drive current corresponding to the voltage applied to the gate electrode of the drive TFT 9d is supplied from the power supply line 20g to the organic EL element 35. Thus, in each subpixel P, the organic EL element 35 emits light the luminance of which corresponds to the drive current. This is how the organic EL display device 50a displays an image.

Described next will be a method for producing the organic EL display device 50a of this embodiment. Note that the method for producing the organic EL display device 50a includes: a TFT-layer forming step, an organic-EL-element-layer forming step, and a sealing-film forming step.

TFT-Layer Forming Step First, for example, a silicon oxide film (approximately 100 nm in thickness) is deposed by, for example, plasma chemical vapor deposition (CVD) on the resin substrate 10 formed on a glass substrate. Hence, the base coat film 11 is formed.

Then, on a substrate surface of the base coat film 11, a metal film such as a molybdenum film (approximately 100 nm in thickness) is formed by, for example, sputtering. After that, the metal film is patterned to form the first gate electrode 12a. Note that when the first gate electrode 12a is formed, the gate line 12g and the light-emission control line 12e are also formed.

After that, on a substrate surface of the first gate electrode 12a, a silicon oxide film (approximately 200 nm in thickness), a silicon nitride film (approximately 30 nm in thickness), and a silicon oxide film (approximately 350 nm in thickness) are deposited in the stated order by, for example, the plasma CVD. Hence, the first gate insulating film 13 is formed.

Furthermore, on a substrate surface of the first gate insulating film 13, an amorphous silicon film (approximately 50 nm in thickness) is deposited by, for example, the plasma CVD. The amorphous silicon film is crystallized by such a technique as laser annealing to form a polysilicon film. The polysilicon film is patterned to form the first semiconductor layer 14a.

Then, using the first gate electrode 12a as a mask, the first semiconductor layer 14a is doped with impurity ions so that a portion of the first semiconductor layer 14a becomes conductive to form the first conductor region 14aa, the second conductor region 14ab, and the first channel region 14ac in the first semiconductor layer 14a.

Then, on a substrate surface of the conductive portion of the first semiconductor layer 14a, a silicon oxide film (approximately 100 nm in thickness) is deposited by, for example, the plasma CVD to form the first interlayer insulating film 15. Furthermore, an oxide semiconductor film (approximately 30 nm in thickness) formed of such a substance as InGaZnO₄ is deposited by sputtering. After that, the oxide semiconductor film is patterned to form the second semiconductor layer 16a.

After that, on a substrate surface of the second semiconductor layer 16a, a silicon oxide film (approximately 100 nm in thickness) is deposited by, for example, the plasma CVD to form the second gate insulating film 17.

Furthermore, on a substrate surface of the second gate insulating film 17, a metal film such as a molybdenum film (approximately 200 nm in thickness) is formed by, for example, sputtering. After that, the metal film is patterned to form the second gate electrode 18a. Note that when the second gate electrode 18a is formed, the second initialization power supply line 18i is also formed.

Then, on a substrate surface of the second gate electrode 18a, a silicon oxide film (approximately 300 nm in thickness) and a silicon nitride film (approximately 150 nm in thickness) are deposited in the stated order by, for example, the plasma CVD. Hence, the second interlayer insulating film 19 is formed. Note that, by heat treatment after the formation of the second interlayer insulating film 19, a portion of the second semiconductor layer 16a becomes conductive to form the third conductor region 16aa, the fourth conductor region 16ab, and the second channel region 16ac in the second semiconductor layer 16a.

After that, the first interlayer insulating film 15, the second gate insulating film 17, and the second interlayer insulating film 19 are patterned as appropriate, so that contact holes such as the first contact hole Ha, the second contact hole Hb, the third contact hole Hc, and the fourth contact hole Hd are formed on a substrate surface of the second interlayer insulating film 19.

Furthermore, on a substrate surface provided with contact holes such as the first contact hole Ha, a titanium film (approximately 50 nm in thickness), an aluminum film (approximately 400 nm in thickness), and a titanium film (approximately 50 nm in thickness) are deposited in the stated order by, for example, sputtering. After that, the multilayer metal film is patterned to form the first terminal electrode 20a, the second terminal electrode 20b, the third terminal electrode 20c, and the fourth terminal electrode 20d. Note that when the first terminal electrode 20a, the second terminal electrode 20b, the third terminal electrode 20c, and the fourth terminal electrode 20d are formed, the source line 20f and the power supply line 20g are also formed.

Finally, substrate surfaces of such electrodes as the first terminal electrode 20a are coated with a polyimide-based photosensitive resin film (approximately 2 μm in thickness) by, for example, spin coating or slit coating. After that, the coating film is pre-baked, exposed to light, developed, and post-baked to form the planarization film 21.

As described above, the TFT layer 30a is successfully formed.

### Organic-EL-Element Layer Forming Step

On the planarization film 21 of the TFT layer 30a formed at the TFT-layer forming step, the first electrode 31, the edge cover 32, the organic EL layer 33 (including the hole injection layer 1, the hole transport layer 2, the light-emitting layer 3, the electron transport layer 4, and the electron injection layer 5), and the second electrode 34 are formed, using a known technique. Hence, the organic EL element layer 40 is formed.

Sealing-Film Forming Step First, on a substrate surface of the organic EL element layer 40 formed at the organic-EL-element-layer forming step, an inorganic insulating film such as, for example, a silicon nitride film, a silicon oxide film, or a silicon oxynitride film is deposited by the plasma CVD, using a mask. Hence, the first inorganic sealing film 41 is formed.

Then, on a substrate surface of the first inorganic sealing film 41, an organic resin material such as acrylic resin is deposited by, for example, inkjet printing. Hence, the organic sealing film 42 is formed.

After that, on a substrate surface of the organic sealing film 42, an inorganic insulating film such as, for example, a silicon nitride film, a silicon oxide film, or a silicon oxynitride film is deposited by the plasma CVD, using a mask, to form the second inorganic sealing film 43. Hence, the first inorganic sealing film 45 is formed.

Finally, a protective sheet (not shown) is attached to a substrate surface of the sealing film 45. After that, a laser beam is emitted from toward the glass substrate of the resin substrate 10, and the glass substrate is removed from a lower surface of the resin substrate layer 10. To the lower surface of the resin substrate layer 10 from which the glass substrate is removed, a protective sheet (not shown) is attached.

As described above, the organic EL display device 50a of this embodiment is successfully produced.

As described above, as to the organic EL display device 50a of this embodiment, each of the first TFTs 9A includes the first gate electrode 12a provided to the first semiconductor layer 14a, which is formed of polysilicon, toward the resin substrate 10 through the first gate insulating film 13. This structure allows the first gate electrode 12a to block the first semiconductor layer 14a from an effect of impurity ions in the resin substrate 10. Thus, the characteristics of the first TFTs 9A can be stabilized. Hence, for the organic EL display device 50a having a hybrid structure using the resin substrate 10, the characteristics of the first TFTs 9A formed of polysilicon semiconductor can be stabilized, and the display quality can be improved.

Furthermore, as to the organic EL display device 50a of this embodiment, each first TFT 9A is a bottom-gate TFT and each second TFT 9B is a top-gate TFT. Such a feature can reduce: parasitic capacitance generated between the first gate electrode 12a of the first TFT 9A and the second gate electrode 18a of the second TFT 9B; and parasitic capacitance generated between the first gate electrode 12a of the first TFT 9A and the second TFT 9B. Moreover, the first gate electrode 12a of the first TFT 9A and the second gate electrode 18a of the second TFT 9B are spaced apart from each other in a thickness direction. Such a feature can reduce a short-circuit failure at an intersection of: the first gate electrode 12a of the first TFT 9A and a wire formed of the same material as, and in the same layer as, the first gate electrode 12a; and the second gate electrode 18a of the second TFT 9B and a wire formed of the same material as, and in the same layer as, the second gate electrode 18a.

Furthermore, as to the organic EL display device 50a of this embodiment, the first gate insulating film 13 is thicker than the second gate insulating film 17. Such a feature can increase an S value of a subthreshold region in an Id-Vg characteristic, and the rise curve can be laid flat. Thus, the first TFT 9A can reduce a variation of a current with respect to a variation of a voltage. Such a feature can reduce luminance variation of the organic EL element 35, thereby successfully obtaining TFT characteristics suitable for the drive TFT 9d. Furthermore, film thicknesses of the first gate insulating film 13 and the second gate insulating film 17 are adjusted, thereby successfully eliminating imbalance caused by a characteristic difference between the first TFT 9A formed of polysilicon semiconductor and the second TFT 9B formed of oxide semiconductor. Thanks to such a feature, the organic EL display device 50a can be designed more flexibly.

Moreover, as to the organic EL display device 50a of this embodiment, the base coat film 11 formed of an inorganic insulating film is provided between the resin substrate 10 and the first gate electrode 12a. Such a feature can keep the first gate electrode 12a from delaminating.

### Second Embodiment

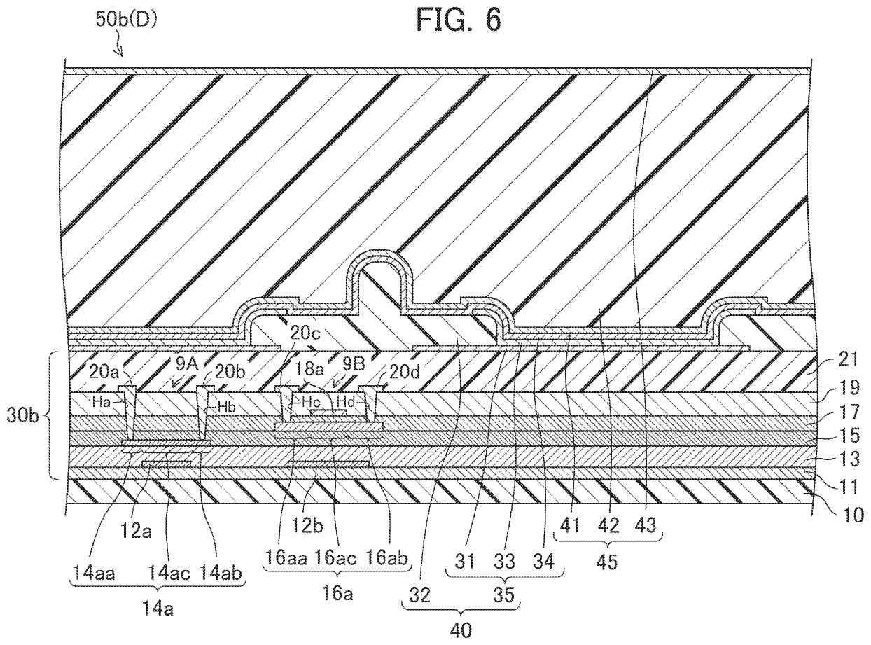

FIG. 6 illustrates a second embodiment of the display device according to the present invention. Here, FIG. 9 is a cross-sectional view of the display region D of an organic EL display device 50b according to this embodiment. FIG. 6 corresponds to FIG. 3 shown in the first embodiment. Note that, in the embodiments below, like reference signs designate identical constituent features throughout FIGS. 1 to 5. These constituent features will not be elaborated upon here.

The first embodiment exemplifies the organic EL display device 50a including no conductive layer provided to the second TFT 9B toward the resin substrate 10. Whereas, this embodiment exemplifies the organic EL display device 50b includes a conductive layer 12b provided to the second TFT 9B toward the resin substrate 10.

Similar to the organic EL display device 50a of the first embodiment, the organic EL display device 50b includes, for example: the display region D shaped into a rectangle; and the picture-frame region F provided around the display region D.

As illustrated in FIG. 6, the organic EL display device 50b includes: the resin substrate layer 10; a TFT layer 30b provided on the resin substrate layer 10; the organic EL element layer 40 provided on the TFT layer 30b; and the sealing film 45 provided to cover the organic EL element layer 40.

The TFT layer 30b illustrated in FIG. 6 includes the base coat film 11 provided on the resin substrate 10; the four first TFTs 9A, the three second TFTs 9B, and the one capacitor 9h all of which are provided on the base coat film 11 for each of the subpixels P (see FIG. 4); and the planarization film 21 provided on each of the first TFTs 9A, the second TFTs 9B, and die capacitor 9h. Here, similar to the TFT layer 30a of the first embodiment, the TFT layer 30b includes: the plurality of gate lines 12, the plurality of light-emission control lines 12e; the plurality of second initialization power supply lines 18i; the plurality of source lines 20f; and the plurality of power supply lines 20g. Furthermore, FIG. 6 shows that, each of the second TFTs 9B includes the conductive layer 12b provided to the second semiconductor layer 16a toward the resin substrate 10. The conductive layer 12b is formed of the same material as, and in the same layer as, the first gate electrode 12a. Note that the conductive layer 12b is electrically floating.

The organic EL display device 50b in the above configuration is similar to the organic EL display device 50a according to the first embodiment. In each subpixel P, the organic EL element 35 emits light the luminance of which corresponds to the drive current. This is how die organic EL display device 50b displays an image.

The organic EL display device 50b of this embodiment can be produced by the method for producing the organic EL display device 50a of the first embodiment. In forming the first gate electrode 12a at the TFT-layer forming step, the conductive layer 12b is formed.

As described above, as to the organic EL display device 50b of this embodiment, each of the first TFTs 9A includes the first gate electrode 12a provided to the first semiconductor layer 14a, which is formed of polysilicon, toward the resin substrate 10 through the first gate insulating film 13. This structure allows the first gate electrode 12a to block the first semiconductor layer 14a from an effect of impurity ions in the resin substrate 10. Thus, the characteristics of the first TFT 9A can be stabilized. Hence, for the organic EL display device 50b having a hybrid structure using the resin substrate 10, the characteristics of the first TFT 9A formed of polysilicon semiconductor can be stabilized, and the display quality can be improved.

Furthermore, as to the organic EL display device 50b of this embodiment, each first TFT 9A is a bottom-gate TFT and each second TFT 9B is a top-gate TFT. Such a feature can reduce: parasitic capacitance generated between the first gate electrode 12a of the first TFT 9A and the second gate electrode 18a of the second TFT 9B; and parasitic capacitance generated between the first gate electrode 12a of the first TFT 9A and the second TFT 9B. Moreover, the first gate electrode 12a of the first TFT 9A and the second gate electrode 18a of the second TFT 9B are spaced apart from each other in a thickness direction. Such a feature can reduce a short-circuit failure at an intersection of: the first gate electrode 12a of the first TFT 9A and a wire formed of the same material as, and in the same layer as, the first gate electrode 12a; and the second gate electrode 18a of the second TFT 9B and a wire formed of the same material as, and in the same layer as, the second gate electrode 18a.

Moreover, as to the organic EL display device 50b of this embodiment, the first gate insulating film 13 is thicker than the second gate insulating film 17. Such a feature can increase an S value of a subthreshold region in an Id-Vg characteristic, and the rise curve can be laid flat. Thus, the first TFT 9A can reduce a variation of a current with respect to a variation of a voltage. Such a feature can reduce luminance variation of the organic EL element 35, thereby successfully obtaining TFT characteristics suitable for the drive TFT 9d Furthermore, film thicknesses of the first gate insulating film 13 and the second gate insulating film 17 are adjusted, thereby successfully eliminating imbalance caused by a characteristic difference between the first TFT 9A formed of polysilicon semiconductor and the second TFT 9B formed of oxide semiconductor. Thanks to such a feature, the organic EL display device 50a can be designed more flexibly.

Moreover, as to the organic EL display device 50b of this embodiment, the base coat film 11 formed of an inorganic insulating film is provided between: the resin substrate 10; and the first gate electrode 12a and the conductive layer 12b. Such a feature can keep the first gate electrode 12a and the conductive layer 12b from delaminating.

In addition, as to the organic EL display device 50b of this embodiment, each of the second TFTs 9B includes the conductive layer 12b provided to the second semiconductor layer 16a toward the resin substrate 10. This structure allows the conductive layer 12b to block the second semiconductor layer 16a from an effect of impurity ions in the resin substrate 10. Thus, the characteristics of the second TFT 9B can be stabilized.

### OTHER EMBODIMENTS

In each of the above embodiments, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Moreover, in each of the above embodiments, the exemplified organic EL display device includes a first electrode as an anode and a second electrode as a cathode. The present invention can also be applied to an organic EL display device whose multilayer structure of the organic EL layer is inverted, and the first electrode is a cathode and the second electrode is an anode.

Furthermore, in each of the above embodiments, the organic EL display device is exemplified as a display device. The present invention is also applicable to a display device including, for example, an active-matrix liquid crystal display device.

In addition, in each of the above embodiment, the exemplified display device is provided with the first TFT and the second TFT for each of the subpixels in the display region. For example, when a p-channel first TFT and a n-channel second TFT are combined together to form a complementary metal oxide semiconductor (CMOS), the present invention is applicable to a display device provided with the first TFT and the second TFT acting as a drive circuit in the picture-frame region.

In addition, in each of the embodiments, the organic EL display device is exemplified as a display device. The present invention is also applicable to a display device including a plurality of light-emitting elements driven by currents. For example, the present invention is applicable to a display device including quantum-dot light-emitting diodes (QLEDs); that is, light-emitting elements including layers containing quantum dots.

### INDUSTRIAL APPLICABILITY

As described above, the present invention is useful for a flexible display device.

### REFERENCE SIGNS LIST

Ha First Contact Hole
Hb Second Contact Hole
Hc Third Contact Hole
Hd Fourth Contact Hole
P Subpixel
9A First TFT (First Thin-Film Transistor)
9B Second TFT (Second Thin-Film Transistor)
9a Initialization TFT (Second Thin-Film Transistor)
9b Compensation TFT (Second Thin-Film Transistor)
9c Write TFT (First Thin-Film Transistor)
9d Drive TFT (First Thin-Film Transistor)
9e Power Supply TFT (First Thin-Film Transistor)
9f Light-Emission Control TFT (First Thin-Film Transistor)
9g Anode Discharge TFT (Second Thin-Film Transistor)
10 Resin Substrate
11 Base Coat Film
12a First Gate Electrode
12b Conductive Layer
13 First Gate Insulating Film
14a First Semiconductor Layer
14aa First Conductor Region
14ab Second Conductor Region
15 First Interlayer Insulating Film
16a Second Semiconductor Layer
16aa Third Conductor Region
16ab Fourth Conductor Region
17 Second Gate Insulating Film
18a Second Gate Electrode
19 Second Interlayer Insulating Film
20a First Terminal Electrode
20b Second Terminal Electrode
20c Third Terminal Electrode
20d Fourth Terminal Electrode
21 Planarization Film
30a and 30b TFT Layer (Thin-Film Transistor Layer)
35 Organic EL Element (Organic Electroluminescence Element, Light-Emitting Element)
40 Organic EL Element Layer (Light-Emitting Element Layer)
45 Sealing Film
50a and 50b Organic EL Display Device

1. A display device, comprising:
a resin substrate; and
a thin-film transistor layer provided on the resin substrate,
wherein the thin-film transistor layer includes a first thin-film transistor and a second thin-film transistor layer both provided for each of subpixels, the first thin-film transistor layer having a first semiconductor layer formed of polysilicon, and a second thin-film transistor having a second semiconductor layer formed of oxide semiconductor,
the first thin-film transistor includes: the first semiconductor layer including a first conductor region and a second conductor region defined to be spaced apart from each other; a first gate electrode provided to the first semiconductor layer toward the resin substrate through a first gate insulating film, and configured to control conduction between the first conductor region and the second conductor region; and a first terminal electrode and a second terminal electrode provided to the first semiconductor layer across from the resin substrate, spaced apart from each other, and respectively and electrically connected to the first conductor region and the second conductor region, and
the second thin-film transistor includes: the second semiconductor layer including a third conductor region and a fourth conductor region positioned more distant from the resin substrate than the first semiconductor layer, and defined to be spaced apart from each other; a second gate electrode provided to the second semiconductor layer across from the resin substrate through a second gate insulating film, and configured to control conduction between the third conductor region and the fourth conductor region; and a third terminal electrode and a fourth terminal electrode provided to the second gate electrode across from the resin substrate, spaced apart from each other, and respectively and electrically connected to the third conductor region and the fourth conductor region.

2. The display device according to claim 1,
wherein, on the first semiconductor layer, a first interlayer insulating film is provided,
on the first interlayer insulating film, the second semiconductor layer is provided,
on the second gate electrode, a second interlayer insulating film is provided,
the first terminal electrode, the second terminal electrode, the third terminal electrode, and the fourth terminal electrode are provided on the second interlayer insulating film,
the first terminal electrode and the second terminal electrode are respectively and electrically connected to the first conductor region and the second conductor region through a first contact hole and a second contact hole formed in a multilayer film including the first interlayer insulating film, the second gate insulating film, and the second interlayer insulating film, and
the third terminal electrode and the fourth terminal electrode are respectively and electrically connected to the third conductor region and the fourth conductor region through a third contact hole and a fourth contact hole formed in a multilayer film including the second gate insulating film and the second interlayer insulating film.

3. The display device according to claim 1,
wherein, on the resin substrate, a base coat film is provided, and
the first gate electrode is provided on the base coat film.

4. The display device according to claim 1,
wherein the first gate insulating film is thicker than the second gate insulating film.

5. The display device according to claim 1, further comprising
a conductive layer provided to the second semiconductor layer toward the resin substrate.

6. The display device according to claim 5,
wherein the conductive layer is formed of a same material as, and in a same layer as, the first gate electrode.

7. The display device according to claim 5,
wherein the conductive layer is electrically floating.

8. The display device according to claim 1,
wherein the thin-film transistor layer includes a planarization film provided to cover the first terminal electrode, the second terminal electrode, the third terminal electrode, and the fourth terminal electrode.

9. The display device according to claim 1, further comprising:
a light-emitting element layer provided on the thin-film transistor layer and having a plurality of light-emitting elements arranged; and
a sealing film provided to cover the light-emitting element layer.

10. The display device according to claim 9,
wherein the first thin-film transistor is a drive thin-film transistor configured to control a current of each of the light-emitting elements.

11. The display device according to claim 9,
wherein each of the light-emitting elements is an organic electroluminescence element.
